(19) United States
(12) Patent Application Publication
(10) Pub. No.: US 2025/0132120 A1
(43) Pub. Date: Apr. 24, 2025

(54) DEVICE AND METHOD FOR VIBRATION FREE LOW TEMPERATURE SAMPLE HOLDER FOR SIDE ENTRY ELECTRON MICROSCOPES

(71) Applicant: Ohio State Innovation Foundation, Columbus, OH (US)

(72) Inventors: Alexander REIFSNYDER, Rye, NY (US); David MCCOMB, New Albany, OH (US)

(21) Appl. No.: 18/293,052

(22) PCT Filed: Jul. 26, 2022
(86) PCT No.: PCT/US2022/038390

§ 371 Date: Jan. 29, 2024

Related U.S. Application Data
(60) Provisional application No. 63/227,494, filed on Jul. 30, 2021.

(51) Int. Cl. H01J 37/20; F25B 21/04

(52) U.S. Cl. CPC H01J 37/20; F25B 21/04; H01J 2237/002; H01J 2237/2001

(57) ABSTRACT

Various implementations include a low temperature sample rod device for side entry electron microscopes. The device includes a conduction rod, a thermoelectric module, a coupler, and a thermal battery. The conduction rod has a first end configured to support a sample. The thermoelectric module has a first side thermally coupled to a second end of the conduction rod. The thermoelectric module is configured to transfer heat between the first side and a second side when supplied with electricity. The coupler has a first coupling surface thermally coupled to the second side of the thermoelectric module. The thermal battery has a battery coupling surface configured to be thermally coupled to a second coupling surface of the coupler. The thermal battery includes a material that can be melted from solid to liquid phase by heat transferred from the conduction rod, through the thermoelectric module, through the coupler, and into the thermal battery.

### CROSS REFERENCE TO RELATED APPLICATIONS

This application claims priority to and benefit of U.S. Provisional Application No. 63/227,494 filed Jul. 30, 2021, the content of which is incorporated herein by reference in its entirety.

### STATEMENT OF GOVERNMENT SUPPORT

This invention was made with government support under grant/contract numbers D18AP00008 awarded by the Defense Advanced Research Projects Agency and 2011876 awarded by the National Science Foundation. The government has certain rights in the invention.

### BACKGROUND

Prior art methods of cooling a sample below ambient temperature for characterization in an electron microscope often use evaporative cooling from liquid nitrogen to cool the sample to approximately 77K. However, the prior art method has a few disadvantages. The most prominent disadvantage is the vibrations transmitted to the sample (thus making long exposure data collection challenging) from the boiling liquid nitrogen as it cools the sample. Liquid nitrogen cooling is also limited to one temperature, the boiling point of nitrogen, without introducing even more vibrations.

Thus, a need exists for cooling a sample below ambient temperature for characterization in an electron microscope that does not introduce disruptive vibration into the sample.

### SUMMARY

Various implementations include a low temperature sample rod device for side entry electron microscopes. The device includes a conduction rod, a thermoelectric module, a coupler, and a thermal battery. The conduction rod has a first end configured to support a sample and a second end opposite and spaced apart from the first end. The thermoelectric module has a first side thermally coupled to the second end of the conduction rod and a second side opposite and spaced apart from the first side. The thermoelectric module is configured to transfer heat between the first side and the second side when supplied with electricity. The coupler has a first coupling surface thermally coupled to the second side of the thermoelectric module and a second coupling surface. The thermal battery has a battery coupling surface configured to be thermally coupled to the second coupling surface. The thermal battery includes a material that can be melted from a solid phase to a liquid phase by heat transferred from the first end of the conduction rod, through the thermoelectric module, through the coupler, and into the thermal battery.

In some implementations, the electron microscope is a transmission electron microscope (“TEM”).

In some implementations, the battery coupling surface of the thermal battery is removably coupled to the second coupling surface. In some implementations, one of the thermal battery and the coupler includes a latching mechanism for removably coupling the thermal battery to the coupler. In some implementations, the latching mechanism includes at least one ball and another of the coupler and the thermal battery includes a detent for receiving the ball to couple the thermal battery to the coupler. In some implementations, the latching mechanism includes a quick release mechanism comprising at least one wedge, and movement of the wedge of the quick release couples the thermal battery to the coupler. In some implementations, the one of the thermal battery and the coupler includes a screw mechanism for removably coupling the thermal battery to the coupler.

In some implementations, the coupler includes a cylinder, and the second coupling surface is defined by a surface of the cylinder. The thermal battery defines a cylindrical opening, and the battery coupling surface is defined by a surface of the opening. In some implementations, the second coupling surface is defined by an outer circumferential surface of the cylinder, and the battery coupling surface is defined by an inner circumferential surface of the opening.

In some implementations, the coupler includes a cone or a conical frustum, and the second coupling surface is defined by an outer circumferential surface of the cone or the conical frustum, wherein the thermal battery defines a conical opening or a frustoconical opening, and the battery coupling surface is defined by an inner circumferential surface of the opening.

In some implementations, the coupler includes a rectangular prism, and the second coupling surface is defined by a surface of the rectangular prism. The thermal battery defines a rectangular opening, and the battery coupling surface is defined by a surface of the opening. In some implementations, the second coupling surface is defined by a radially facing surface of the rectangular prism, and the battery coupling surface is defined by a radially facing surface of the opening.

In some implementations, the second coupling surface is defined by an axially facing surface of the coupler, and the battery coupling surface is defined by an axially facing surface of the thermal battery.

In some implementations, the coupler has a longitudinal axis and the second coupling surface is defined by a surface of the coupler that forms an oblique angle with the longitudinal axis of the coupler. The thermal battery has a longitudinal axis and the battery coupling surface is defined by a surface of the thermal battery that forms an oblique angle with the longitudinal axis of the thermal battery. The longitudinal axis of the coupler is axially aligned with the longitudinal axis of the thermal battery.

In some implementations, the material includes water. In some implementations, the material includes glycerin. In some implementations, the material includes propane.

In some implementations, one of the second coupling surface and the battery coupling surface includes a thermal interface material coating. In some implementations, the thermal interface material coating includes a thermal paste or thermal adhesive. In some implementations, the thermal interface material coating includes a soft or liquid metal.

### BRIEF DESCRIPTION OF DRAWINGS

Example features and implementations of the present disclosure are disclosed in the accompanying drawings. However, the present disclosure is not limited to the precise arrangements and instrumentalities shown. Similar elements in different implementations are designated using the same reference numerals.

FIG. 1 is a side view of a low temperature sample rod device for side entry electron microscopes, according to one implementation.

FIG. 2A is a side view of the latching mechanism of the device of FIG. 1 in an engaged position.

FIG. 2B is a side view of the latching mechanism of the device of FIG. 1 in a disengaged position.

FIG. 3 is a side view of a coupler and a thermal battery of a low temperature sample rod device for side entry electron microscopes, according to some implementations.

FIG. 4A is a side view of a coupler and a thermal battery with a latching mechanism in the engaged position, according to some implementations.

FIG. 4B is a side view of the coupler and the thermal battery of FIG. 4A with the latching mechanism in the disengaged position.

FIG. 5A is a side view of a coupler and a thermal battery with a latching mechanism, according to some implementations.

FIG. 5B is a side view of a coupler and a thermal battery with a latching mechanism, according to some implementations.

### DETAILED DESCRIPTION

The devices, systems, and methods disclosed herein provide for cooling samples below ambient temperature for characterization in an electron microscope, such as a transmission electron microscope (“TEM”). However, the devices, systems, and methods described herein can also be applied to other types of electron microscopes, such as a scanning electron microscope (“SEM”). The devices, systems, and methods described herein provide for cooling a sample down to 233K or lower, in a manner that is free of disruptively large vibrations. This is accomplished using a device including a thermoelectric cooler (“TEC”) disposed at the end of a sample rod such that the TEC is disposed outside of the microscope in use. A thermal conduction rod transmits the cooling from the TEC, through a feedthrough of the microscope, to a high vacuum environment within the microscope. The conduction rod transitions to a thermal braid of the device, which cools the sample. The thermal braid reduces vibrations, if any, that may be carried through the conduction rod to the sample.

TECs are a type of solid-state heat pump that operates without the flow of fluids or gasses. When an electrical current flows through a TEC in a first direction, the TEC causes heat to transfer from a cooling portion of the TEC to a heating portion of the TEC. When the electrical current is caused to flow in a second direction that is opposite the first direction, the TEC causes the heat to transfer from the heating portion to the cooling portion. Flowing gases in other systems cause vibrations that can be transferred to a sample, which can disrupt long exposure times needed for electron microscopes. Because TECs and other solid-state heat pump systems do not utilize gas flow, these systems produce minimum vibrations.

However, TECs do need to reject the heat they pump along with the waste heat they generate during pumping. For current TECs, each watt of thermal energy that the TEC pumps from the cooling side creates an additional watt of thermal energy that must be rejected. Thus, for every watt of cooling performed by a TEC, it must reject approximately two watts from the hot side. The rejection of heat from a TEC is traditionally accomplished with a heat sink cooled by air or water. However, the introduction of air or water to cool a TEC would introduce vibrations. Additionally, it is difficult with this type of heat sink to achieve a stable temperature at the sample.

To solve this problem, various implementations of the devices, systems, and methods described herein reject heat into a “thermal battery,” which contains a frozen mixture of glycerin and water. The glycerin lowers the melting point of the thermal battery mixture without significantly disrupting the latent heat of melting of the mixture. The thermal battery absorbs the rejected heat by melting some of the mixture.

Using only the thermal battery, instead of using the thermal battery in combination with a TEC, would increase of the life of the thermal battery, since the TEC generates additional waste energy as it operates. However, by using the thermal battery with a TEC, the devices, systems, and methods described herein allow the coolants within the thermal battery, like water mixtures (which reach insufficient temperatures), to reach useful temperatures at the sample. The TEC included in the devices, systems, and methods described herein allows the sample to reach any temperature between the temperature of the coolant and the maximum cooling provided by the TEC.

In addition, by reversing the polarity, the TEC can also be used to heat the sample from the temperature of the coolant to about 333K.

Various implementations include a low temperature sample rod device for side entry electron microscopes. The device includes a conduction rod, a thermoelectric module, a coupler, and a thermal battery. The conduction rod has a first end configured to support a sample and a second end opposite and spaced apart from the first end. The thermoelectric module has a first side thermally coupled to the second end of the conduction rod and a second side opposite and spaced apart from the first side. The thermoelectric module is configured to transfer heat between the first side and the second side when supplied with electricity. The coupler has a first coupling surface thermally coupled to the second side of the thermoelectric module and a second coupling surface. The thermal battery has a battery coupling surface configured to be thermally coupled to the second coupling surface. The thermal battery includes a material that can be melted from a solid phase to a liquid phase by heat transferred from the first end of the conduction rod, through the thermoelectric module, through the coupler, and into the thermal battery.

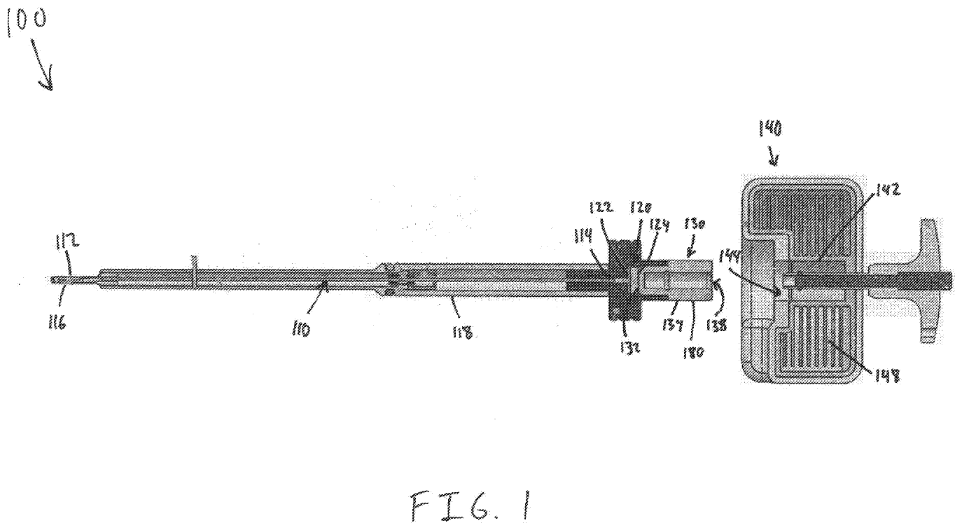

FIG. 1 shows a low temperature sample rod device 100 for side entry electron microscopes according to aspects of various implementations. The device 100 includes a conduction rod 110, a thermoelectric module 120, a coupler 130, and a thermal battery 140.

The conduction rod 110 extends through a rod sheathing 118. The conduction rod 110 is used to transfer heat from a sample within the electron microscope out of the electron microscope. The rod sheathing 118 shown in FIG. 1 is shaped to be partially disposed within a transmission electron microscope (“TEM”), however in other implementations, the rod sheathing is designed for use with any other microscope.

The conduction rod 110 has a first end 112 and a second end 114 opposite and spaced apart from the first end 112. A ceramic insert 116 is coupled to the first end 112 of the conduction rod 110, and the first end 112 of the conduction rod 110 is configured to support a sample to be observed inside of the electron microscope. The rod sheathing 118 helps to insulate the conduction rod 110 when the conduction rod 110 is transferring heat from the first end 112 of the conduction rod 110 to the thermoelectric module 120, as discussed below.

The thermoelectric module 120, also called a thermoelectric cooler (“TEC”), has a first side 122 thermally coupled to the second end 114 of the conduction rod 110 and a second side 124 opposite and spaced apart from the first side 122. The thermoelectric module 120 is configured to transfer heat between the first side 122 of the thermoelectric module 120 and the second side 124 of the thermoelectric module 120 when the thermoelectric module 120 is supplied with electricity. The thermoelectric module 120 shown in FIG. 1 is a Peltier heat pump, but in other implementations, the thermoelectric module can be any solid-state device capable of forced heat transfer.

As discussed above, one of the issues with cooling a specimen within an electron microscope is that many cooling systems introduce vibrations into the specimen, making the specimen difficult, if not impossible, to observe. The solid-state design of the thermoelectric module 120 shown in FIG. 1 does not include any moving parts and, thus, does not introduce vibration into the system.

The coupler 130 has a first coupling surface 132 thermally coupled to the second side 124 of the thermoelectric module 120 and a second coupling surface 134. The thermal battery 140 has a battery coupling surface 142 configured to be thermally coupled to the second coupling surface 132 of the coupler 130. For the device 100 shown in FIG. 1, the battery coupling surface 142 of the thermal battery 140 is removably coupled to the second coupling surface 132 of the coupler 130 such that the thermal battery 140 can be removed from the rest of the device 100 and can be either recharged or replaced with another thermal battery. However, in other implementations, the thermal battery is integrally coupled to the coupler or another portion of the device.

The coupler 130 shown in FIG. 1 includes a cylinder, and the second coupling surface 134 is defined by an outer circumferential surface of the cylinder. The thermal battery 140 defines a complimentary cylindrical opening 144, and the battery coupling surface 142 is defined by an inner circumferential surface of the opening 144. The tight tolerances of the cylinder and the opening shown in FIG. 1 assure that the coupler 130 and the thermal battery 140 make as much thermal contact as possible to allow for the maximum conduction of heat across the coupling for this configuration. Although the cylinder and the opening shown in FIG. 1 allow for thermal contact of the cylinder and the opening along circumferential surfaces, it should be noted that the cylinder and the opening can also have thermal contact between axial surfaces.

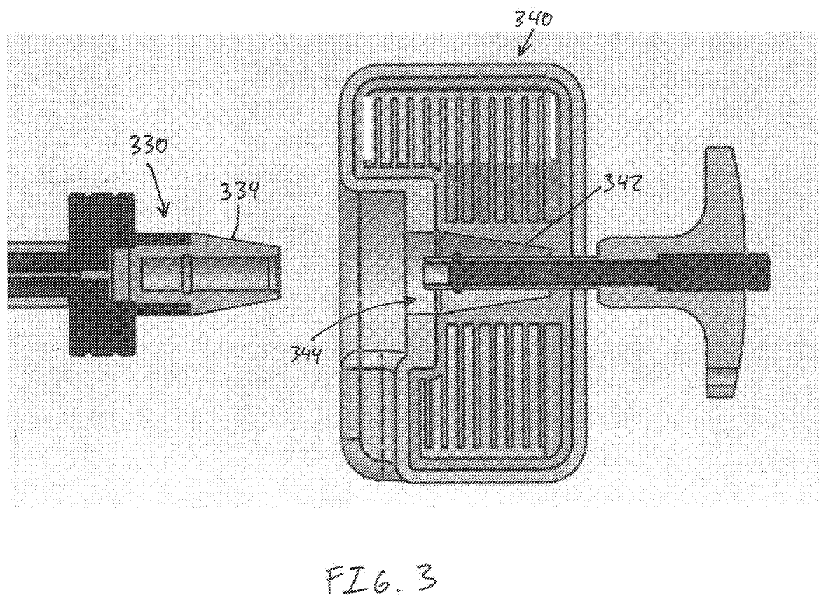

FIG. 3 shows another implementation of a coupler 330 and thermal battery 340 similar to the coupler 130 and thermal battery 140 shown in FIG. 1, but the coupler 330 shown in FIG. 3 includes a conical frustum, and the second coupling surface 334 is defined by an outer circumferential surface of the conical frustum. The thermal battery 340 shown in FIG. 3 defines a complimentary frustoconical opening 344, and the battery coupling surface 342 is defined by an inner circumferential surface of the opening 344. The coupler 330 and thermal battery 340 shown in FIG. 3 can be used interchangeably and in combination with any of the features shown in FIG. 1.

The tight tolerances of the conical frustum and the opening shown in FIG. 3 assure that the coupler 330 and the thermal battery 340 make as much thermal contact as possible to allow for the maximum conduction of heat across the coupling for this configuration. The tapering circumferential surface of the conical frustum and the opening also ensure tight tolerances as the coupler 330 is axially inserted into the opening 344. Although the conical frustum and the opening shown in FIG. 3 allow for thermal contact of the conical frustum and the opening along circumferential surfaces, it should be noted that the conical frustum and the opening can also have thermal contact between axial surfaces. In some implementations, the coupler includes a fully conical shape, and the thermal battery defines a complementary, fully conical opening.

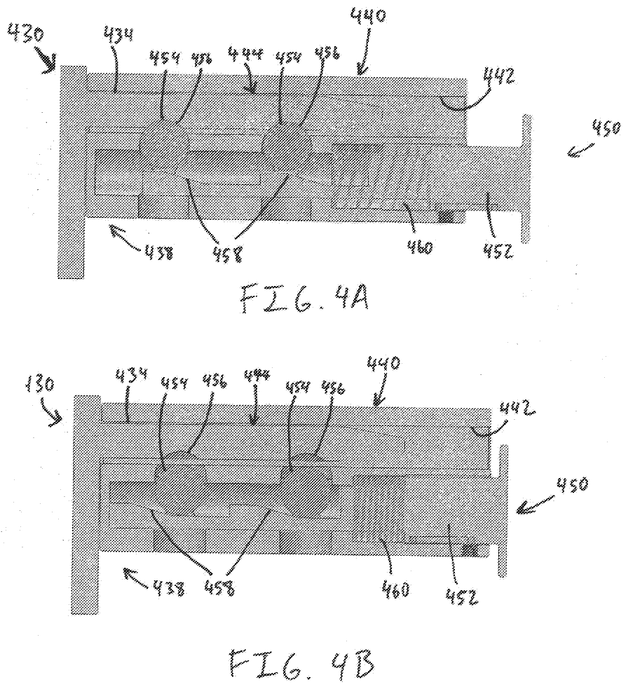

FIGS. 4A and 4B show another implementation of a coupler 430 and thermal battery 440 similar to the coupler 130 and thermal battery 140 shown in FIG. 1, but the coupler 430 shown in FIGS. 4A and 4B includes a rectangular prism, and the second coupling surface 434 is defined by radially facing surfaces of the rectangular prism. The thermal battery 440 shown in FIGS. 4A and 4B defines a rectangular opening 444, and the battery coupling surface 442 is defined by radially facing surfaces of the opening 444. The coupler 430 and thermal battery 440 shown in FIGS. 4A and 4B can be used interchangeably and in combination with any of the features shown in FIG. 1.

The tight tolerances of the rectangular prism and the opening shown in FIGS. 4A and 4B assure that the coupler 430 and the thermal battery 440 make as much thermal contact as possible to allow for the maximum conduction of heat across the coupling for this configuration. The flat thermal contact surfaces of the rectangular prism and the opening also make it easier to manufacture tight tolerances between the coupler 430 and the opening 444 of the thermal battery 440. Although the rectangular prism and the opening shown in FIGS. 4A and 4B allow for thermal contact of the rectangular prism and the opening along radially facing surfaces, it should be noted that the rectangular prism and the opening can also have thermal contact between axial end surfaces.

Although FIGS. 1-4B show three different shaped couplers and complimentary shaped openings, in some implementations, the coupler can have any other shape and the thermal battery can define a complimentary shaped opening. In some implementations, the thermal battery includes any shape of protruding surface, such as those described above with respect to the coupler, or any other shape, and the coupler defines a complimentary opening as described above with respect to thermal batteries.

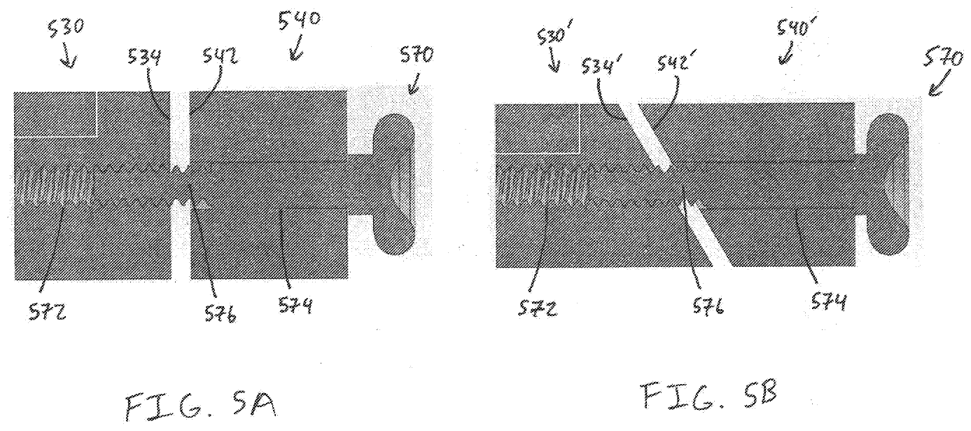

FIG. 5A shows another implementation of a coupler 530 and thermal battery 540 similar to the coupler 130 and thermal battery 140 shown in FIG. 1, but the coupler 530 shown in FIG. 5A includes an axially facing second coupling surface 534 of the coupler 530, and the thermal battery 540 includes a battery coupling surface 542 that is defined by an axially facing surface of the thermal battery 540. The coupler 530 and thermal battery 540 shown in FIG. 5A can be used interchangeably and in combination with any of the features shown in FIG. 1.

FIG. 5B shows another implementation of a coupler 530′ and thermal battery 540′ similar to the coupler 530 and thermal battery 540 shown in FIG. 5A, but the coupler 530′ shown in FIG. 5B has a longitudinal axis 536′ and the second coupling surface 534′ is defined by a surface of the coupler 530′ that forms an oblique angle with the longitudinal axis 536′ of the coupler 530′. The thermal battery 540′ shown in FIG. 5B has a longitudinal axis 546′ and the battery coupling surface 542′ is defined by a surface of the thermal battery 540′ that forms a complimentary oblique angle with the longitudinal axis 546′ of the thermal battery 540′ such that the second coupling surface 534′ and the battery coupling surface 542′ are parallel to each other. Thus, the longitudinal axis 536′ of the coupler 530′ is axially alignable with the longitudinal axis 546′ of the thermal battery 540′ such that the second coupling surface 534′ and the battery coupling surface 542′ can make thermal contact with each other. Like with the implementation shown in FIG. 5A, the coupler 530′ and thermal battery 540′ shown in FIG. 5B can be used interchangeably and in combination with any of the features shown in FIG. 1.

In some implementations, the second coupling surface includes any shaped or angled surface, such as convex, concave, ridges, textures, indentations, or protrusions, and the thermal coupling surface defines a complimentary shape or angle.

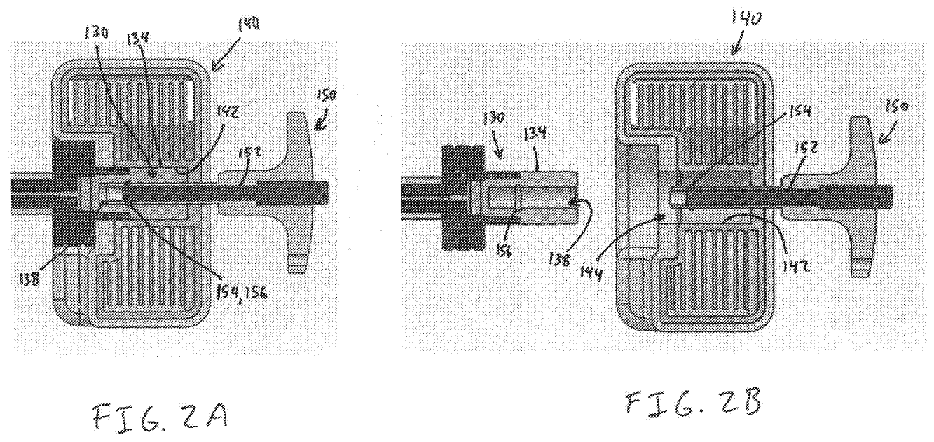

The thermal battery 140 and the coupler 130 shown in FIG. 1 includes a latching mechanism 150 for removably coupling the thermal battery 140 to the coupler 130. The latching mechanism 150 of FIG. 1 is shown in detail in FIGS. 2A and 2B. The latching mechanism 150 includes a quick release mechanism having an axially sliding quick release rod 152 in the thermal battery 140. The quick release rod 152 includes a radially extending detent protrusion 154. The radially extending detent protrusion 154 is made of a resilient material such that it can be radially inwardly depressed.

The latching mechanism 150 also includes an axially extending opening 138 of the coupler 130 that is sized to receive an end of the quick release rod 152. The inner circumferential wall of the opening 138 of the coupler 130 defines a circumferentially extending detent groove 156 sized to receive the radially extending detent protrusion 154 of the quick release rod 152 when the end of the quick release rod 152 is inserted into the opening 138 of the coupler 130. The radially extending detent protrusion 154 within the circumferentially extending detent groove 156 retains the coupler 130 within the opening 144 of the thermal battery 140 to prevent the coupler 130 from inadvertently axially exiting the opening 144 of the thermal battery 140, as shown in FIG. 2A.

When the quick release rod 152 is axially slid relative to the thermal battery 140 the radially extending detent protrusion 154 is resiliently depressed radially inwardly such that the radially extending detent protrusion 154 is able to be removed from the circumferentially extending detent groove 156. In this position, the radially extending detent protrusion 154 and the circumferentially extending detent groove 156 of the latching mechanism 150 no longer retain the coupler 130 within the opening 144 of the thermal battery 140, and the thermal battery 140 can be removed from the coupler 130, as shown in FIG. 2B.

Although the latching mechanism 150 shown in FIGS. 1-2B includes a resiliently deformable radially extending detent protrusion 154, in some implementations, the latching mechanism can include a radially extending detent ball or any other feature that can be resiliently moved out of the detent groove. In some implementations, the latching mechanism includes two or more radially extending detent protrusions or balls and corresponding two or more grooves or openings. In some implementations, the coupler includes the radially extending detent protrusion(s) or ball(s) and the quick release rod defines the circumferentially extending detent groove(s) or opening(s).

FIGS. 4A and 4B show another implementation of a latching mechanism 450 similar to the latching mechanism 150 shown in FIGS. 1-2B, but the latching mechanism 450 shown in FIGS. 4A and 4B includes a quick release mechanism that includes a quick release rod 452 with detent balls 454 and wedges 458. The latching mechanism 450 shown in FIGS. 4A and 4B can be used interchangeably and in combination with any of the features shown in FIG. 1-5B.

The quick release rod 452 shown in FIGS. 4A and 4B includes two axially sliding wedges 458 that are axially slidable from a first position (shown in FIG. 4A) to a second position (shown in FIG. 4B). The latching mechanism 450 includes two captured detent balls 454 that are forced into a radially outwardly extending position when the wedges 458 are moved into the first position, as shown in FIG. 4A. In the radially outwardly extending position, the two detent balls 454 are disposed within, and engage with, corresponding detent openings 456 of the coupler 430.

When the two wedges 458 are moved to the second position, the two captured detent balls 454 move to a radially inwardly retracted position, as shown in FIG. 4B. In the radially inwardly retracted position, the two detent balls 454 are removed from, and disengage with, the corresponding detent openings 456 of the coupler 430.

The latching mechanism 450 also includes a spring 460 to bias the quick release rod 452 and the two wedges 458 toward the first position, as shown in FIG. 4A. The quick release rod 452 and the two wedges 458 can be urged toward the second position, as shown in FIG. 4B.

For the latching mechanism 450 shown in FIGS. 4A and 4B, the thermal battery 440 can be thermally coupled to the coupler 430 by urging the quick release rod 452 and wedges 458 toward the second position such that the two detent balls 454 move to the radially inwardly retracted position. The coupler 430 can then be inserted into the opening 444 of the thermal battery 440 such that at least a portion of the quick release rod 452 is inserted into the opening 438 of the coupler 430. In this position, the detent openings 456 of the coupler 430 are radially aligned with the corresponding detent balls 454. The user can then allow the spring 460 to bias the quick release rod 452 and wedges back 458 to the first position such that the detent balls 454 are disposed within, and engage with, corresponding detent openings 456 of the coupler 430. In this position, the detent balls 454 within the detent openings 456 retains the coupler 430 within the opening 444 of the thermal battery 440 to prevent the coupler 430 from inadvertently axially exiting the opening 444 of the thermal battery 440.

The thermal battery 440 can be removed from the coupler 430 by again urging the quick release rod 452 and wedges 458 toward the second position and axially moving the thermal battery 440 such that the coupler 430 is no longer disposed within the opening 444 of the thermal battery 440.

The latching mechanisms 150, 450 shown in FIGS. 1, 4A, and 4B can be used to thermally couple the coupler 130, 430 to the thermal battery 140, 440 in a way that introduces minimal vibration into the system, minimizing the disruption of the imaging within the electron microscope. Thermal batteries have a finite lifetime, determined by the coolant's latent heat of fusion, and often must be replaced with a fresh battery during imaging. Thus, a latching mechanism for retaining a removable thermal battery that introduces a minimal amount of disruptive vibration into the system is beneficial.

FIGS. 5A and 5B show another implementation of a latching mechanism 570 similar to the latching mechanism 150 shown in FIG. 1, but the latching mechanism 570 shown in FIGS. 5A and 5B includes screw mechanism for removably coupling the thermal battery 540 to the coupler 530. The latching mechanism 570 shown in FIGS. 5A and 5B can be used interchangeably and in combination with any of the features shown in FIG. 1-5B.

The screw mechanism 570 includes a threaded opening 572 defined by the coupler 530, a screw opening 574 defined by the thermal battery 540, and a screw 576 extending through the screw opening 574. To thermally couple the coupler 530 to the thermal battery 540, the threaded portion of the screw 576 is threaded into the threaded opening 572 of the coupler 530. The screw 576 forces the battery coupling surface 542 against the second coupling surface 534 to ensure that the coupler 530 and the thermal battery 540 are thermally coupled. Although the screw mechanism 570 shown in FIGS. 5A and 5B includes a threaded opening 572 defined by the coupler 530 and a screw opening 574 defined by the thermal battery 540, in some implementations, the screw mechanism includes a threaded opening defined by the thermal battery and a screw opening defined by the coupler. In some implementations, the screw mechanism can include two or more threaded openings, two or more corresponding screw openings, and two or more screws each disposed within a different one of the two or more screw openings.

The thermal battery 140 shown in FIG. 1 includes a material 148 that can be melted from a solid phase to a liquid phase by heat transferred from the first end 112 of the conduction rod 110, through the thermoelectric module 120, through the coupler 130, and into the thermal battery 140. A thermal battery using a solid to liquid phase change does not introduce vibrations to the system when absorbing energy and transitioning between phases.

In contrast, a liquid phase to gas phase transition results in boiling of the liquid as the gas separates from the liquid. The boiling causes vibration, which can disturb the imaging within the electron microscope.

Similarly, forced convection cooling for heat removal can causes vibrations in the system. In forced convection, a fluid is caused to pass over a heat surface, such as exposed heat sink fins. The fluid flow over the heat surface can cause vibrations in the system, which can disturb the imaging within the electron microscope.

Passive cooling methods, such as passive convective or conductive cooling at ambient temperatures, can introduce less vibrations into the system, but can suffer from low heat transfer. Similarly, materials that are cooled but will not transition through a phase change during use often do not have enough latent heat of fusion ΔHf to be effective. Thus, a thermal battery using these materials may need to be replaced too often to be effective.

The material 148 used in the thermal battery 140 shown in FIG. 1 is a water/glycerin mixture, which has a high latent heat of fusion ΔHr and can absorb a relatively large amount of heat energy during a transition from solid phase to liquid phase. In some implementations, the material can be only water. In some implementations, the material can be propane. In some implementations, the material can include any material that can be frozen into a solid phase and will transition to a liquid phase when heat from the sample is transferred to the thermal battery material by the thermoelectric module.

In some implementations, the material of the thermal battery and the thermoelectric module can transfer enough heat from the sample to reduce the temperature of the sample to as low as 76K. In some implementations, the material of the thermal battery and the thermoelectric module can transfer enough heat from the sample to reduce the temperature of the sample to as low as 233K.

In some situations, it may be desirable to heat the sample rather than cooling it. The voltage direction supplied to the thermoelectric module can also be reversed to cause the thermoelectric module to heat the sample and remove heat from the thermal battery. In some implementations, the material of the thermal battery and the thermoelectric module can transfer enough heat to the sample to increase the temperature of the sample to as high as 473K.

The second coupling surface 134 of the coupler 130 can further include a thermal interface material coating 180. The thermal interface material coating 180 can fill any gaps between the second coupling surface 134 of the coupler 130 and the battery coupling surface 142 of the thermal battery 140 caused by tolerances in the features. The thermal interface material coating 180 allows the heat to transfer by conduction through the thermal interface material coating rather than through an air gap between the features to increase heat flux. The thermal interface material coating 180 shown in FIG. 1 is a thermal paste, but in some implementations, the thermal interface material coating can include a thermal adhesive, a thermal padding, or a layer of soft or liquid metal, such as lead, tin, indium, or gallium.

A number of example implementations are provided herein. However, it is understood that various modifications can be made without departing from the spirit and scope of the disclosure herein. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. Although the terms “comprising” and “including” have been used herein to describe various implementations, the terms “consisting essentially of” and “consisting of” can be used in place of “comprising” and “including” to provide for more specific implementations and are also disclosed.

Disclosed are materials, systems, devices, methods, compositions, and components that can be used for, can be used in conjunction with, can be used in preparation for, or are products of the disclosed methods, systems, and devices. These and other components are disclosed herein, and it is understood that when combinations, subsets, interactions, groups, etc. of these components are disclosed that while specific reference of each various individual and collective combinations and permutations of these components may not be explicitly disclosed, each is specifically contemplated and described herein. For example, if a device is disclosed and discussed each and every combination and permutation of the device are disclosed herein, and the modifications that are possible are specifically contemplated unless specifically indicated to the contrary. Likewise, any subset or combination of these is also specifically contemplated and disclosed. This concept applies to all aspects of this disclosure including, but not limited to, steps in methods using the disclosed systems or devices. Thus, if there are a variety of additional steps that can be performed, it is understood that each of these additional steps can be performed with any specific method steps or combination of method steps of the disclosed methods, and that each such combination or subset of combinations is specifically contemplated and should be considered disclosed.

What is claimed is:

1. A low temperature sample rod device for side entry electron microscopes, the device comprising:
a conduction rod having a first end configured to support a sample and a second end opposite and spaced apart from the first end;
a thermoelectric module having a first side thermally coupled to the second end of the conduction rod and a second side opposite and spaced apart from the first side, wherein the thermoelectric module is configured to transfer heat between the first side and the second side when supplied with electricity;
a coupler having a first coupling surface thermally coupled to the second side of the thermoelectric module and a second coupling surface; and
a thermal battery having a battery coupling surface configured to be thermally coupled to the second coupling surface, wherein the thermal battery includes a material that can be melted from a solid phase to a liquid phase by heat transferred from the first end of the conduction rod, through the thermoelectric module, through the coupler, and into the thermal battery.

2. The device of claim 1, wherein the electron microscope is a transmission electron microscope (“TEM”).

3. The device of claim 1, wherein the battery coupling surface of the thermal battery is removably coupled to the second coupling surface.

4. The device of claim 3, wherein one of the thermal battery and the coupler includes a latching mechanism for removably coupling the thermal battery to the coupler.

5. The device of claim 4, wherein the latching mechanism includes at least one ball and another of the coupler and the thermal battery includes a detent for receiving the ball to couple the thermal battery to the coupler.

6. The device of claim 4, wherein the latching mechanism includes a quick release mechanism comprising at least one wedge, wherein movement of the wedge of the quick release couples the thermal battery to the coupler.

7. The device of claim 3, wherein the one of the thermal battery and the coupler includes a screw mechanism for removably coupling the thermal battery to the coupler.

8. The device of claim 1, wherein the coupler includes a cylinder, and the second coupling surface is defined by a surface of the cylinder, wherein the thermal battery defines a cylindrical opening, and the battery coupling surface is defined by a surface of the opening.

9. The device of claim 8, wherein the second coupling surface is defined by an outer circumferential surface of the cylinder, and the battery coupling surface is defined by an inner circumferential surface of the opening.

10. The device of claim 1, wherein the coupler includes a cone or a conical frustum, and the second coupling surface is defined by an outer circumferential surface of the cone or the conical frustum, wherein the thermal battery defines a conical opening or a frustoconical opening, and the battery coupling surface is defined by an inner circumferential surface of the opening.

11. The device of claim 1, wherein the coupler includes a rectangular prism, and the second coupling surface is defined by a surface of the rectangular prism, wherein the thermal battery defines a rectangular opening, and the battery coupling surface is defined by a surface of the opening.

12. The device of claim 11, wherein the second coupling surface is defined by a radially facing surface of the rectangular prism, and the battery coupling surface is defined by a radially facing surface of the opening.

13. The device of claim 1, wherein the second coupling surface is defined by an axially facing surface of the coupler, and the battery coupling surface is defined by an axially facing surface of the thermal battery.

14. The device of claim 1, wherein the coupler has a longitudinal axis and the second coupling surface is defined by a surface of the coupler that forms an oblique angle with the longitudinal axis of the coupler, wherein the thermal battery has a longitudinal axis and the battery coupling surface is defined by a surface of the thermal battery that forms an oblique angle with the longitudinal axis of the thermal battery, wherein the longitudinal axis of the coupler is axially aligned with the longitudinal axis of the thermal battery.

15. The device of claim 1, wherein the material comprises water.

16. The device of claim 1, wherein the material comprises glycerin.

17. The device of claim 1, wherein the material comprises propane.

18. The device of claim 1, wherein one of the second coupling surface and the battery coupling surface includes a thermal interface material coating.

19. The device of claim 18, wherein the thermal interface material coating comprises a thermal paste or thermal adhesive.

20. The device of claim 18, wherein the thermal interface material coating comprises a soft or liquid metal.
